(19) United States
(12) Patent Application Publication
(10) Pub. No.: US 2024/0341108 A1
(43) Pub. Date: Oct. 10, 2024

(54) SINGLE CHIRALITY sc-SWCNT AND USES THEREOF IN PHOTO-ACTIVE DEVICES

(71) Applicant: National Research Council of Canada, Ottawa (CA)

(72) Inventors: Zhao LI, Orleans (CA); Jianying OUYANG, Gloucester (CA); Jianfu DING, Ottawa (CA); Patrick R. L. MALENFANT, Ottawa (CA)

(73) Assignee: National Research Council of Canada, Ottawa, ON (CA)

(21) Appl. No.: 18/293,522

(22) PCT Filed: Aug. 8, 2022
(86) PCT No.: PCT/CA2022/051206

§ 371 Date: Jan. 30, 2024

Related U.S. Application Data
(60) Provisional application No. 63/232,685, filed on Aug. 13, 2021.

(51) Int. Cl. H10K 30/65; H10K 30/80; H10K 71/13; H10K 71/40; H10K 85/20; H10K 101/30; H10K 101/40

(52) U.S. Cl. CPC H10K 30/65; H10K 30/865; H10K 71/13; H10K 71/40; H10K 85/211; H10K 85/221; H10K 2101/30; H10K 2101/40

(57) ABSTRACT

A composition for use in a photo-active device has: a charge transfer network of single walled carbon nanotubes (SWCNT) having at least 95 wt % of semiconducting single walled carbon nanotubes (sc-SWCNT) based on total weight of the SWCNT, the sc-SWCNT containing at least 30 wt % of one chiral type of sc-SWCNT based on total weight of the sc-SWCNT; and, a solution processible electron trapping material of a fullerene compound, the electron trapping material in contact with the charge transfer network of SWCNT. The composition is readily prepared from solution processible components and is highly sensitive in a narrow wavelength band. The composition is particularly useful in photoconductors and phototransistors that operate on the infrared region of the electromagnetic spectrum.

### CROSS-REFERENCE TO RELATED APPLICATIONS

This application claims the benefit of U.S. Provisional Patent Application No. 63/232,685 filed Aug. 13, 2021, the entire contents of which is herein incorporated by reference.

### FIELD

This application relates to single chirality semiconducting single-walled carbon nanotubes (sc-SWCNT), photo-active compositions comprising single chirality sc-SWCNT, their uses in photo-active devices and processes for producing such photo-active devices.

### BACKGROUND

Single-walled carbon nanotube (SWCNT) materials have great potential in photonic and optoelectronic devices. Depending on how the carbon-atom honeycomb sheets roll up, SWCNTs can be either semiconductors (sc-SWCNT) or metals (m-SWCNT). These two kinds of materials have to be efficiently separated for various application areas due to their dramatically different electrical properties. Recent rapid development of purification process for sc-SWCNTs, such as conjugated polymer extraction, has further boosted interest in their applications for photonics and electronics through low-cost large scale production process (e.g., printing) and/or on flexible substrates (e.g., plastics).

Depending on their diameters and chiralities, sc-SWCNTs have distinct band gaps corresponding to specific absorption and fluorescence wavelength. Single chirality SWCNTs are highly desired for band/spectral selective applications. The separation of single chirality sc-SWCNTs has been initially investigated by DNA sequence selective wrapping or column gel chromatography. However, the yield from these water-based systems is usually quite low, which may be enough for optical characterization, but not enough for electrical applications. More recently, conjugated polymer extraction has appeared as a promising method for single chirality sc-SWCNTs enrichment. High purity single chirality tubes, such as (6,5), (7,5), (9,8) and (15,4) have been reported, and high yield can be realized if raw materials from chirality selective synthetic approach have been used.

Photodetectors have become important in people's daily life, from silicon-based CCD camera on smart phone to digital cinematography. Photodetectors operating in near infrared (NIR) and infrared (IR) range are particularly attractive in applications including night vision, environmental monitoring and medical imaging. Traditional materials used for NIR or IR application are usually inorganic based, such as silicon, InGaAs, HgCdTe, etc. Processing of these materials is based on traditional semiconductor industry processes in which high vacuum and high temperature are used leading to high cost and environment related issues.

Different materials combinations, such as pure sc-SWCNTs, sc-SWCNT/polymer, sc-SWCNT/graphene and sc-SWCNT/C₆₀, have been tested. SWCNT-only devices utilizing thermal or bolometric effects caused by photo irradiation, usually have poor response and slow response. It has also been reported that addition of a thin layer of C₆₀ can significantly enhance IR sensitivity of sc-SWCNT-based photodetectors. Following this trend, similar work has been done using the combination of sc-SWCNTs and C₆₀ as active materials for photodetectors. Where a mixture of sc-SWCNTs have been used in devices, the devices usually exhibit broad absorption spectra. Further, photodetectors based on such materials demonstrate response to a broad wavelength range and therefore have no spectral selectivity. In addition, C₆₀ has poor processibility and poor solubility in solvents. Also, broad tube distribution resulting in broad absorption characteristics leads to poor device sensitivity at certain wavelengths.

There remains a need for active materials for photo-active devices (e.g., NIR or IR photodetectors), which can be easily fabricated by low cost and scalable process, have high responsivity and sensitivity, and utilize environmentally friendly materials.

### SUMMARY

Described herein is a composition for use in a photo-active device comprising: a charge transfer network of single walled carbon nanotubes (SWCNT) comprising at least 95 wt % of semiconducting single walled carbon nanotubes (sc-SWCNT) based on total weight of the SWCNT, the sc-SWCNT comprising at least 30 wt % of one chiral type of sc-SWCNT based on total weight of the sc-SWCNT; and, a solution processible electron trapping material comprising a fullerene compound, the electron trapping material in contact with the charge transfer network of SWCNT, wherein the electron trapping material has a lowest unoccupied molecular orbital (LUMO) that is higher in energy than a highest occupied molecular orbital (HOMO) energy level of the one chiral type and is at least 0.1 eV lower than a lowest unoccupied molecular orbital (LUMO) energy level of the one chiral type.

Also described herein is a photo-active device comprising: a substrate; a source electrode disposed on the substrate; a drain electrode disposed on the substrate; and, the composition as defined above disposed on the substrate and in contact with the source electrode and the drain electrode to permit electrical current to flow between the source and drain electrodes through the charge transfer network of SWCNT.

Also described herein is a process for producing a photo-active device, the process comprising: depositing a source electrode and a drain electrode on a substrate; and either (a) depositing on the substrate, between the source electrode and the drain electrode, a composition comprising a charge transfer network of single walled carbon nanotubes (SWCNT) such that the network is in contact with the source and drain electrodes to permit electrical current to flow between the source and drain electrodes through the charge transfer network, and depositing on the charge transfer network a solution processible electron trapping material comprising a fullerene compound, or (b) depositing on the substrate, between the source electrode and the drain electrode, a composition comprising a charge transfer network of single walled carbon nanotubes (SWCNT) homogeneously mixed with a solution processible electron trapping material comprising a fullerene compound to permit electrical current to flow between the source and drain electrodes through the charge transfer network, wherein in both (a) and (b) the charge transfer network of SWCNT comprises at least 95 wt % of semiconducting single walled carbon nanotubes (sc-SWCNT) based on total weight of the SWCNT, the sc-SWCNT comprising at least 30 wt % of one chiral type of sc-SWCNT based on total weight of the sc-SWCNT, and wherein in both (a) and (b) the electron trapping material has a lowest unoccupied molecular orbital (LUMO) energy level that is higher in energy than a highest occupied molecular orbital (HOMO) energy level of the one chiral type and at least 0.1 eV lower than a lowest unoccupied molecular orbital (LUMO) energy level of the one chiral type.

The compositions possess one or more of the following: high responsivity, high sensitivity arising from narrow spectral selectivity, producible by a low-cost process, producible by a scalable process and producible from environmentally friendly materials. The sc-SWCNTs have distinct and narrow absorption bands, for example in the near infrared (NIR) region, depending on the diameters of the sc-SWCNTs. Spectral regime is determined by the particular chiral species of sc-SWCNT used in the composition.

A photo-active device is capable of responding to light. Photo-active refers to the property of being able to absorb light, and in response, undergo or produce a change in a property, function, or output. Some examples of photo-active devices include photodiodes, photoconductors and phototransistors. Photoconductors and phototransistors are particularly preferred. Commercial applications of photo-active devices based on the composition of the present invention include, for example, night vision, remote sensing, environmental monitoring, medical imaging, food inspection, surveillance and security.

Further features will be described or will become apparent in the course of the following detailed description. It should be understood that each feature described herein may be utilized in any combination with any one or more of the other described features, and that each feature does not necessarily rely on the presence of another feature except where evident to one of skill in the art.

### BRIEF DESCRIPTION OF THE DRAWINGS

For clearer understanding, preferred embodiments will now be described in detail by way of example, with reference to the accompanying drawings, in which:

FIG. 1A depicts a schematic diagram of a photoconductor.

FIG. 1B depicts a schematic diagram of a first embodiment of a phototransistor.

FIG. 1C depicts a schematic diagram of a second embodiment of a phototransistor.

FIG. 2 depicts absorption spectra of solution samples for (6,5), (7,5) and (9,8) single chirality enriched sc-SWCNTs.

FIG. 3 depicts a transmission spectrum of narrow optical bands in a range of 750-1550 nm produced using a super-continuum laser covering 450-2400 nm together with various band pass filters.

FIG. 4 depicts a graph of source-drain current (A) versus time(s) with light at different wavelengths switched on and off repeatedly comparing a photo-active device having a photo-active layer comprising (6,5) single chirality enriched sc-SWCNT and PCBM₇₁ (upper curve) to a device having a photo-active layer comprising only (6,5) single chirality enriched sc-SWCNT (lower curve). The devices' channel length and width are 2.5 μm and 2 mm, respectively. Vsd and Vg were set at 1 V and −20 V, respectively.

FIG. 5 depicts a graph of source-drain current change (A) versus time(s) with light at 1000 nm at various power densities for a photoconductor device having a photo-active layer comprising (6,5) single chirality enriched sc-SWCNT and PCBM₇₁. The left axis applies to the main curve and the right axis applies to the ×10 magnified inset for the 100 nW and 10 nW data points at the right of the graph.

FIG. 6 depicts a graph of source drain current change (A) versus input optical power (W) within the channel of the photoconductor device indicated in FIG. 5.

FIG. 7 depicts a graph of source-drain current change (% of current change) versus wavelength (nm) for (6,5) and (7,5) sc-SWNCT-based photodetector devices.

### DETAILED DESCRIPTION

The composition comprises a charge transfer network of single walled carbon nanotubes (SWCNT). The charge transfer network comprises a two-dimensional or three-dimensional film containing SWNCTs that are sufficiently interconnected in the film to enable transfer of charge between a source and a drain electrode of a device through the charge transfer network disposed between and in electrical contact with the source and drain electrodes. When SWCNTs absorb electromagnetic radiation, electrons of the SWCNTs are excited into higher energy states thereby generating an electrical signal that can be propagated through the charge transfer network. While the SWCNTs are sufficiently interconnected with tube-to-tube contact to enable transfer of charge between the source and drain electrodes, the film of SWCNTs may cover less than 100%, or even less than 50%, of a surface of a substrate on which the film is deposited. A practical lower limit of surface coverage of the substrate by the film containing SWCNTs is about 10%. Charge transfer preferably comprises an electrical current between the source and drain electrodes. The network of SWNCTs preferably is sufficiently interconnected to permit an electrical current of at least 1×10⁻⁹ A to flow between the source and drain electrodes when the composition is irradiated with electromagnetic radiation at a wavelength that can be absorbed by the sc-SWCNT in the film.

The film of SWCNTs comprises at least 95 wt % of semiconducting single walled carbon nanotubes (sc-SWCNT) based on total weight of the SWCNT, preferably at least 98 wt %, more preferably at least 99 wt %, yet more preferably at least 99.5 wt %.

The sc-SWCNT comprises at least 30 wt % of one chiral type of sc-SWCNT based on total weight of the sc-SWCNT, preferably at least 40 wt %, more preferably at least 50 wt %, yet more preferably at least 65 wt %, still more preferably at least 75 wt %, even yet more preferably at least 85 wt %, most preferably at least 90 wt %. Single chirality sc-SWCNTs are highly desired for band/spectral selective applications. While sc-SWCNT are preferably highly enriched in one chiral type to provide a more selective response to a particular wavelength of electromagnetic radiation, preferably in the infrared (IR) region of the electromagnetic spectrum, optical performance of sc-SWCNT not as highly enriched in one chiral type can be improved in a device by using filters to limit the wavelength band of the electromagnetic radiation to compensate for the lessened selectivity of the less chirally pure sc-SWCNT.

The chiral type of sc-SWCNT is preferably (6,4) (6,5), (7,5), (7,6), (8,6), (8,7), (9,1), (9,8) or (10,9). More preferably, the chiral type of sc-SWCNT is (6,5), (7,5) or (9,8).

The SWCNTs preferably have average diameters in a range of 0.4 nm to 40 nm, more preferably 0.6 nm to 2.2 nm. The SWCNTs preferably have lengths in a range of 50 nm to 5000 nm, more preferably 100 nm to 3000 nm. The chiral type of sc-SWCNT determines the diameter of the sc-SWCNT, and impact optical performance of the composition and devices based on the composition. Optical performance can be tuned for a given application by selecting the chiral type and diameters of the sc-SWCNT that provide the best responsivity and detectivity for that application. Because single chirality enriched sc-SWCNTs have a narrow absorption spectrum in certain wavelength band, which is pre-determined by the diameter and chirality of the sc-SWCNT, photo-active devices based on such single chirality sc-SWCNTs will therefore have maximum absorption in the same or similar spectral regime, thereby realizing spectral selectivity. Single chirality enriched sc-SWCNTs have much narrower bandgap distribution, thus high sensitivity can be expected at certain wavelengths.

As-produced SWCNTs are generally a mixture of sc-SWCNT an m-SWCNT, for example as-produced HiPCo SWCNTs comprise about two-thirds sc-SWCNT and one-third m-SWCNT. Further enrichment of the SWCNT to higher levels of sc-SWCNT can be done in a number of different known ways, for example by extraction with a conjugated polymer. General techniques for extracting SWCNTs are described, for example, in U.S. Pat. No. 10,046,970 issued Aug. 14, 2018 and Ding J, et al. Nanoscale, 2014, 6, 2328, the entire contents of both of which herein incorporated by reference. The SWCNTs may therefore be wrapped with a conjugated polymer. Conjugated polymers include, for example, polyfluorenes, polythiophenes, polyphenylenevinylenes, and their copolymers with one or more co-monomer units (e.g., bithiophene, phenylene, bipyridine, anthracene, naphthalene and benzothiadiazole) or combinations thereof. The conjugated polymer preferably comprises a polyfluorene derivative, for example a 9,9-dialkyl-substituted polyfluorene, or a 9,9-diC₁₀₋₃₆-alkyl-substituted polyfluorene, or a 9,9-dic₁₀₋₁₈-alkyl-substituted polyfluorene. Poly(9,9-di-n-dodecylfluorene) (PFDD) is one example of a polyfluorene derivative. Choice of conjugated polymer for the extraction can determine which chiral type of sc-SWCNT is preferentially enhanced, for example as described in Ozawa H, et al. Chem. Lett. 2011, 40, 239241, Ozawa H, et al. J. Am. Chem. Soc. 2011, 133, 2651-2657 and Si R, et al. Chem. Asian J. 2014, 9, 868-877, the entire contents of all of which herein incorporated by reference.

The composition also comprises a solution processible electron trapping material in contact with the charge transfer network of SWCNT. The electron trapping material is capable of accepting an electron from the one chiral type of sc-SWCNT after the electron is excited into a higher energy state by absorbing electromagnetic radiation incident on the sc-SWCNT film. To facilitate transfer of an excited electron from the one chiral type of sc-SWCNT to the electron trapping material, the electron trapping material has a lowest unoccupied molecular orbital (LUMO) that is higher in energy than a highest occupied molecular orbital (HOMO) energy level of the one chiral type and is at least 0.1 eV lower than a lowest unoccupied molecular orbital (LUMO) energy level of the one chiral type. Preferably, the LUMO of the electron trapping material is at least 0.15 eV lower, more preferably at least 0.2 eV lower, than the LUMO energy level of the one chiral type. Preferably, the LUMO of the electron trapping material is −4.0 eV or lower vs. vacuum energy.

The solution processible electron trapping material preferably comprises a fullerene compound, more preferably a phenyl butyric acid methyl ester derivative of fullerene. The fullerene is preferably C₆₁ or C₇₁. Most preferred, the electron trapping material comprises [6,6]-phenyl C₆₁ butyric acid methyl ester ((PCBM₆₁), [6,6]-phenyl C₇₁ butyric acid methyl ester (PCBM₇₁) or a mixture thereof.

The electron trapping material and the SWCNT may form a bilayer with a contact interface between a first layer comprising the electron trapping material and a second layer comprising the SWCNTs. Or, the electron trapping material may be homogeneously mixed with the SWCNTs. Or, the electron trapping material and the SWCNTs may form a bilayer with the electron trapping material interpenetrating into a SWCNT layer. A mixture is a material comprising two or more different substances which are not chemically combined and in which the separate identities of the two or more different substances are retained. The mixture may be homogeneous or heterogeneous. A homogeneous mixture displays substantially uniform characteristics throughout the material, whereas a heterogeneous mixture displays significant localized differences in characteristics in the material. A material having a layer of electron trapping material interpenetrating into a layer of SWCNTs would be a heterogeneous mixture.

The electron trapping material is in contact with the the charge transfer network of SWCNTs which will form a continuous network to carry charge to the source and drain electrodes of a device. However, the conductivity of the electron trapping material is generally poorer than the SWCNTs.

The electron trapping material is advantageously easily processed in solution to permit solution-based deposition of the trapping material during fabrication of the photo-active device. In particular, [6,6]-phenyl C₆₁ butyric acid methyl ester and [6,6]-phenyl C₇₁ butyric acid methyl ester offer an excellent combination of easy processing and band gap matching with important single chirality sc-SWCNT such as (6,5), (7,5) and (9,8). Together, [6,6]-phenyl C₆₁ butyric acid methyl ester or [6,6]-phenyl C₇₁ butyric acid methyl ester with (6,5), (7,5) or (9,8) provide a photo-active composition that is produced readily by common solution processing techniques such as printing while being highly sensitive to a narrow wavelength band in the infrared (IR) region of the electromagnetic spectrum. For example, in a photoconductor or phototransistor device structure, a bilayer or mixture of a single chirality enriched SWCNTs and [6,6]-phenyl C₆₁ butyric acid methyl ester or [6,6]-phenyl C₇₁ butyric acid methyl ester (PCBM) provides highly sensitive and spectral selective response. Finding an electron trapping material that is solution processible while having a band gap that matches the band gap of single chirality sc-SWCNTs is very difficult to realize in practice.

Photo-active devices that employ the composition may be fabricated by applying generally known techniques, for example the techniques described in Li Z, et al. Organic Electronics 26 (2015) 15-19 and Ding J, et al. Nanoscale, 2014, 6, 2328, the entire contents of both of which herein incorporated by reference.

Photo-active devices utilizing the composition comprise: a substrate; a source electrode disposed on the substrate; a drain electrode disposed on the substrate; and, the composition described above disposed on the substrate and in contact with the source electrode and the drain electrode to permit electrical current to flow between the source and drain electrodes through the charge transfer network of SWCNT.

The substrate may comprise: an electrical insulator, for example when the device is a photoconductor; or, an electrical conductor, for example when the device is a phototransistor. Insulators include, for example, glass, silicon dioxide, plastic, paper and the like. Conductors include, for example, metal (e.g., gold, silver, copper, titanium, mixtures thereof, alloys thereof or the like), doped silicon (e.g., silicon doped with B, C, P, Al, In, As, Sb or the like). Where doped silicon is the conductor, the silicon is preferably heavily doped having a doping concentration of greater than about 1×10¹⁶ cm⁻³, preferably up to about 1×10¹⁸ cm⁻³. When the substrate is a conductor, the substrate may function as a gate. The gate may be a top gate or a bottom gate. When a gate is employed, the charge transfer network of SWCNT may be separated from the gate by a gate dielectric disposed between the gate and the charge transfer network of SWCNT. The gate dielectric comprises an electrically insulating material, for example silicon dioxide, hafnium silicate, zirconium silicate, hafnium dioxide, zirconium dioxide, any polymer dielectric or the like. Silicon dioxide is a preferred gate dielectric. In some embodiments, the substrate is a first substrate and the device further comprises a second substrate, wherein the composition is disposed between the first and second substrates, and the second substrate is an electrical insulator.

The source and drain electrodes comprise an electrically conductive material, preferably a metal. The metal preferably comprises Au, Ag, Cu, Ti, Pd or the like, or conductive mixtures or alloys thereof. The metal more preferably is Au, Ag, Ti or Pd.

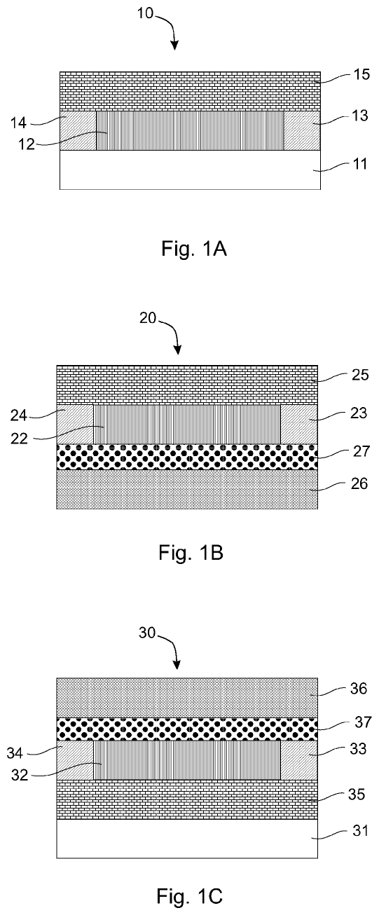

Photo-active devices may be fabricated in a variety of configurations to fulfill certain purposes. FIG. 1A, FIG. 1B and FIG. 1C illustrate three common configurations.

FIG. 1A depicts a schematic diagram of a photoconductor 10 in which the composition comprises a bilayer in which a layer of electron trapping material 15 is deposited on a layer comprising a charge transfer network of SWCNT 12 to form an interface where the electron trapping material 15 contacts the charge transfer network of SWCNT 12. The charge transfer network of SWCNT 12 is deposited directly on an electrically insulating substrate 11 between a source electrode 13 and a drain electrode 14 also deposited directly on the substrate 11. The charge transfer network of SWCNT 12 is in contact with both the source electrode 13 and the drain electrode 14. The electron trapping material 15 is also deposited directly on the source electrode 13 and the drain electrode 14.

FIG. 1B depicts a schematic diagram of a first embodiment of a phototransistor 20 in which a charge transfer network of SWCNT 22, an electron trapping material 25, a source electrode 23 and a drain electrode 24 are configured in the same manner as in the photoconductor of FIG. 1A. However, instead of an electrically insulating substrate, the phototransistor 20 comprises a substrate comprising a bottom gate 26, the bottom gate 26 supporting the charge transfer network of SWCNT 22, the source electrode 23 and the drain electrode 24, whereby the bottom gate 26 is separated from the charge transfer network of SWCNT 22, the source electrode 23 and the drain electrode 24 by a gate dielectric 27. The charge transfer network of SWCNT 22 is in contact with the gate dielectric 27 at an interface between the two.

FIG. 1C depicts a schematic diagram of a second embodiment of a phototransistor 30 in which the composition comprises a bilayer in which a layer comprising a charge transfer network of SWCNT 32 is deposited on a layer of electron trapping material 35 to form an interface where the electron trapping material 35 contacts the charge transfer network of SWCNT 32. The charge transfer network of SWCNT 32 is deposited directly on the electron trapping material 35 between a source electrode 33 and a drain electrode 34, which are also deposited directly on the electron trapping material 35. The electron trapping material 35 is deposited directly on an electrically insulating substrate 31. The phototransistor 30 comprises a top gate 36 above the charge transfer network of SWCNT 32, the source electrode 33 and the drain electrode 34, whereby the top gate 36 is separated from the charge transfer network of SWCNT 32, the source electrode 33 and the drain electrode 34 by a gate dielectric 37.

The process for producing the photo-active device comprises building layers of materials, preferably in a bottom-to-up fashion. In some embodiments, a substrate is provided, whether electrically insulating or electrically conducting, and the source electrode and drain electrode are deposited on the substrate either directly, or in the case where the substrate is electrically conducting, by first depositing a layer of dielectric material on the substrate followed by depositing the source and drain electrodes on the layer of dielectric material.

A composition comprising the charge transfer network of SWCNT may then be deposited on the substrate between the source electrode and the drain electrode such that the network is in contact with the source and drain electrodes to permit electrical current to flow between the source and drain electrodes through the charge transfer network. A composition comprising the electron trapping material may then be deposited on the charge transfer network. Alternatively, the electron trapping material can be deposited before the depositing the charge transfer network of SWCNT on the electron trapping material. Alternatively, a composition comprising the charge transfer network of SWCNT homogeneously mixed with the electron trapping material may be deposited on the substrate between the source electrode and the drain electrode to form a bulk heterojunction that permits electrical current to flow between the source and drain electrodes through the charge transfer network. Preferably, the composition comprising the charge transfer network is deposited on the substrate before the electron trapping material is deposited on the composition comprising the charge transfer network.

Any suitable deposition processes may be used to deposit the electrodes (source, drain, gate), the charge transfer network of SWCNT, the electron trapping material, any dielectric used and any other component of the device on the substrate, either directly on the substrate or on a layer of another material that is supported on the substrate. Some examples of deposition methods include solution or dispersion processing techniques (e.g., printing, dip coating, drop casting and the like) and vapor phase techniques (e.g., vacuum evaporation, sputtering and the like). Preferably, all of the components of the device are deposited by solution or dispersion processing techniques, which provides a low-cost, scalable process for the production of photo-active devices. Solution or dispersion deposition techniques include, for example, printing, dip coating, drop casting and the like. In particular, printing methods are preferred for deposition. Printing methods include, for example, screen printing, inkjet printing, flexography printing (e.g., stamps), gravure printing, off-set printing, airbrushing, aerosol printing, typesetting, or any other like method. In some embodiments, the depositing of the charge transfer network is accomplished by printing; the depositing of the electron trapping material is accomplished by printing; or, both the depositing of the charge transfer network and the electron trapping material are accomplished by printing.

Solution processing of the electron trapping layer should involve solvents that are not detrimental to carbon nanotubes. Further, the solvent should be sufficiently volatile to be evaporated either at ambient temperature or with the application of heat and/or vacuum. Organic solvents are preferred, for example toluene, xylene, tetrahydrofuran and the like. Concentration of the electron trapping material in the solvent is preferably in a range of 0.1-10 wt %. The polarity of the solvent may be chosen depending on the type of composition desired for the application. Because the SWCNT are generally wrapped in a hydrophobic polymer, use of a hydrophobic solvent to process the electron trapping material is useful to produce either a heterojunction if the electron trapping material is mixed with the SWCNTs prior to deposition or a bilayer with the electron trapping material interpenetrating into the charge transfer network of SWCNTs if the electron trapping material is deposited on to an already deposited charge transfer network of SWCNTs. On the other hand, use of a hydrophilic solvent to process the electron trapping material is useful to produce a composition comprising a bilayer of the charge transfer network of SWCNTs and the electron trapping material, the bilayer having a sharply defined interface between the charge transfer network of SWCNTs and the electron trapping material.

Especially for phototransistor applications, good contact between the charge transfer network of SWCNT and the substrate or gate dielectric is beneficial for functioning of the photo-active device. To promote adhesion of the charge transfer network of SWCNT to the substrate or gate dielectric, an annealing step at elevated temperature may be performed. The annealing temperature is preferably in a range of 50-450° C., for example 200° C. Annealing is preferably done for a time over 0.1 hours, preferably for 10-90 minutes, for example 1 hour. Annealing may be performed under ambient conditions or in a glove box.

### EXAMPLES

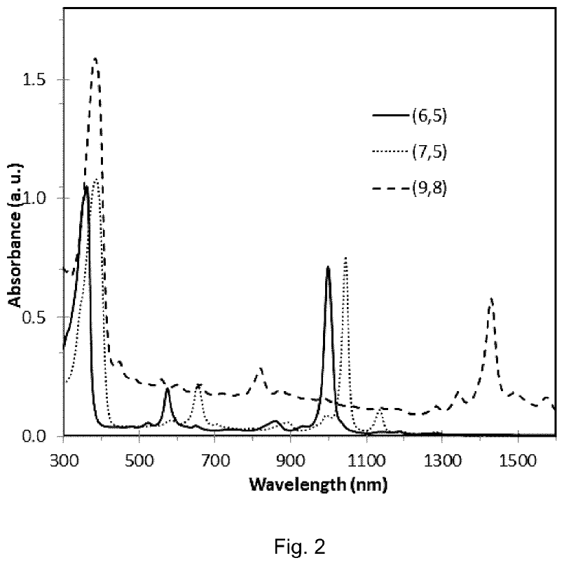

FIG. 2 depicts the absorption spectra of solution samples for (6,5), (7,5) and (9,8) single chirality sc-SWCNTs enriched through a conjugated polymer extraction process. Ultraviolet-visible-near-IR (UV-vis-NIR) absorption spectra were collected by using a 1 nm data interval (Varian Cary™ 5000 spectrophotometer). The samples demonstrate narrow absorption bands closely related to their energy gaps (S11). The maximum absorption peaks of S11 for (6,5), (7,5) (9,8) sc-SWCNTs are at 1001 nm, 1046 nm and 1432 nm respectively. FIG. 2 shows that (6,5), (7,5) and (9,8) single chirality sc-SWCNTs are excellent candidates for infrared-bases photo-active devices.

To test the usefulness of compositions described herein in photo-active devices, thin-film transistor (TFT) devices were fabricated with composition comprising:
(C1) a charge transfer network of SWCNT enriched in (6,5) single chirality sc-SWCNT;
(S1) a charge transfer network of SWCNT enriched in (6,5) single chirality sc-SWCNT and a PCBM₇₁ electron trapping layer deposited on top of the charge transfer network; and,
(S2) a charge transfer network of SWCNT enriched in (7,5) single chirality sc-SWCNT and a PCBM₇₁ electron trapping layer deposited on top of the charge transfer network.

The single chirality SWCNT samples were prepared in accordance with the procedure described in Ozawa H, et al. Chem. Lett. 2011, 40, 239-241, whereby the (6,5) sample was prepared using PFO-Bpy to obtain a purity of (6,5) sc-SWCNT of about 93% based on total weight of sc-SWCNT, and whereby the (7,5) was prepared using PFO obtain a purity of (7,5) sc-SWCNT of about 84% based on total weight of sc-SWCNT.

The devices were fabricated in a manner similar to the TFT devices described in Ding J, et al. Nanoscale, 2014, 6, 2328-2339 and Li Z, et al. Organic Electronics 26 (2015) 15-19. Briefly, the devices were fabricated on a silicon wafer with a 100 nm thick thermal silicon oxide (SiO₂) layer. The wafer was first cleaned using Piranha solution (1:2 (v/v) of 98% H₂SO₄ and 35% H₂O₂) for 30 min at 90° C. After thoroughly rinsing with distilled water and isopropanol, the wafer was blow-dried with nitrogen. Polyfluorene/SWCNT dispersions in toluene were bath sonicated for 5 min immediately before usage. The tube solution was spread on the SiO₂ layer for 10 min under toluene vapor, not allowing the solvent to evaporate to form a chip with a charge transfer network of the SWCNT on a silicon dioxide substrate. Then the chip was rinsed with 5 ml of toluene and blow-dried with nitrogen before being annealed at 200° C. for 1 h under ambient pressure. Drain and source electrodes (5 nm Ti followed by 100 nm Pd) were deposited through a shadow mask using an e-beam evaporator. The channel width is 2 mm and the channel length is 2.5 μm. For S1 and S2, a PCBM₇₁ top layer was applied by drop casting or spin coating using a 1 wt % solution of PCBM₇₁ in xylene.

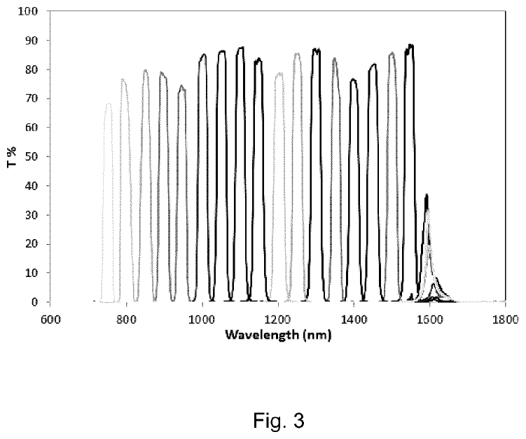

Responsivity of the devices between 750 nm and 1550 nm was measured by using a supercontinuum laser source model SC-5 from YSL Photonics™ covering 450-2400 nm. Narrow bands in this wavelength range were obtained by passing the light through a combination of appropriate 25 nm band-pass filters. The power intensity at each band was controlled by the laser output and attenuation filters, and was calibrated by a digital power meter. FIG. 3 depicts a transmission spectrum of narrow optical bands in the range of 750-1550 nm produced using the super-continuum laser together with various band pass filters. From FIG. 3, it is evident that clean and narrow optical bands covering a wavelength range of 750-1550 nm can be obtained.

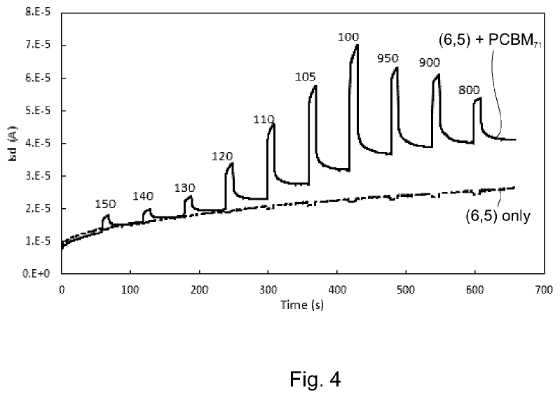

As seen in FIG. 4, by switching the laser light on and off repeatedly at different wavelengths and the same power density, the TFT photodetector S1, comprising (6,5) single chirality enriched sc-SWCNT and PCBM₇₁, gives the highest response at the maximum absorption peak of 1000 nm for the (6,5) single chirality SWCNTs, and exhibits lower response at other wavelengths, perhaps due to the broadened absorption bands of (6,5) single chirality SWCNTs in a solid thin film. For the device C1, comprising (6,5) single chirality enriched sc-SWCNT but no PCBM₇₁, there is no response.

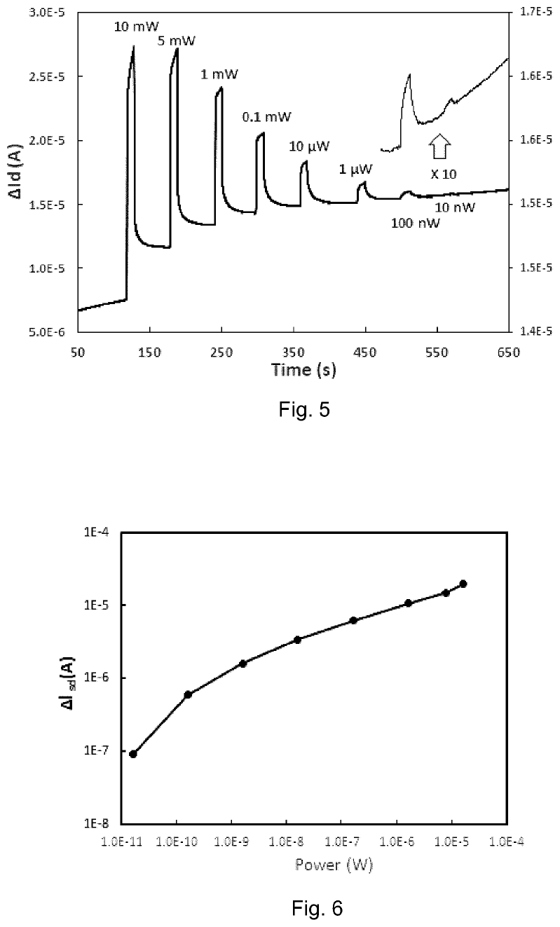

FIG. 5 shows current change at different power densities when the TFT S1 is irradiated at the 1000 nm band, while FIG. 6 shows the change of current versus input power within the channel. The photodetector S1 shows a wide dynamic range up to 6 magnitudes towards the input optical power. The responsivity can be over 3000 A/W even when very weak light (<1.6×10⁻¹⁰ W) was irradiated within the channel.

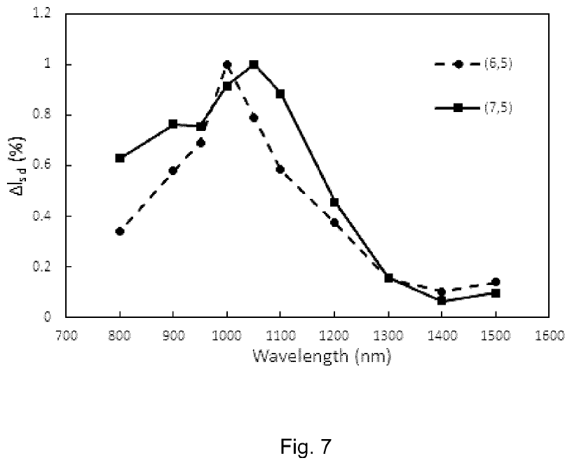

FIG. 7 shows the percentage of current change for the (6,5)-based TFT photodetector (S1) and the (7,5)-based photodetector. Both of these photodetectors show spectrally selective responses corresponding to the absorption maximum of the single chirality SWCNT used.

The novel features will become apparent to those of skill in the art upon examination of the description. It should be understood, however, that the scope of the claims should not be limited by the embodiments, but should be given the broadest interpretation consistent with the wording of the claims and the specification as a whole.

1. A composition for use in a photo-active device, the composition comprising:
a charge transfer network of single walled carbon nanotubes (SWCNT) comprising at least 95 wt % of semiconducting single walled carbon nanotubes (sc-SWCNT) based on total weight of the SWCNT, the sc-SWCNT comprising at least 30 wt % of one chiral type of sc-SWCNT based on total weight of the sc-SWCNT; and,
a solution processible electron trapping material comprising a fullerene compound, the electron trapping material in contact with the charge transfer network of SWCNT,
wherein the electron trapping material has a lowest unoccupied molecular orbital (LUMO) that is higher in energy than a highest occupied molecular orbital (HOMO) energy level of the one chiral type and is at least 0.1 eV lower than a lowest unoccupied molecular orbital (LUMO) energy level of the one chiral type.

2. The composition of claim 1, wherein the LUMO of the electron trapping material is at least 0.2 eV lower than the LUMO energy level of the one chiral type, the LUMO of the electron trapping material is −4.0 eV or lower vs. vacuum energy or the LUMO of the electron trapping material is both at least 0.2 eV lower than the LUMO energy level of the one chiral type and −4.0 eV or lower vs. vacuum energy.

3. (canceled)

4. The composition of claim 1, wherein the sc-SWCNT comprises at least 50 wt % of the one chiral type.

5. The composition of claim 1, wherein the sc-SWCNT comprises at least 75 wt % of the one chiral type.

6. The composition of claim 1, wherein the sc-SWCNT comprises at least 90 wt % of the one chiral type.

7. The composition of claim 1, wherein the SWCNTs are wrapped with a conjugated polymer, wherein the one chiral type is (6,5), (7,5) or (9,8) or wherein the SWCNTs are wrapped with a conjugated polymer and the one chiral type is (6,5), (7,5) or (9,8).

8. (canceled)

9. The composition of claim 1, wherein the one chiral type is (6,5), (7,5) or (9,8) and the electron trapping material comprises [6,6]-phenyl C₆₁ butyric acid methyl ester or [6,6]-phenyl C₇₁ butyric acid methyl ester.

10. The composition of claim 1, wherein:
the electron trapping material is homogeneously mixed with the SWCNT;
the electron trapping material and the SWCNT form a bilayer with a contact interface between a first layer comprising the electron trapping material and a second layer comprising the SWCNT; or,
the electron trapping material and the SWCNT form a bilayer with the electron trapping material interpenetrating into the SWCNT.

12. (canceled)

13. A photo-active device comprising:
a substrate;
a source electrode disposed on the substrate;
a drain electrode disposed on the substrate; and,
the composition as defined claim 1 disposed on the substrate and in contact with the source electrode and the drain electrode to permit electrical current to flow between the source and drain electrodes through the charge transfer network of SWCNT.

14. The device of claim 13, wherein the device is a photoconductor and the substrate is an electrical insulator.

15. The device of claim 14, wherein the substrate comprises glass.

16. The device of claim 15, wherein the device is a phototransistor and the substrate comprises a gate.

17. The device of claim 16, wherein the substrate further comprises a gate dielectric disposed between the gate and the charge transfer network of SWCNT.

18. The device of claim 17, wherein the gate comprises doped silicon, the gate dielectric comprises silicon dioxide, or both the gate comprises doped silicon and the gate dielectric comprises silicon dioxide.

19. The device of claim 13, wherein the substrate is a first substrate and the device further comprises a second substrate, wherein the composition is disposed between the first and second substrates, and the second substrate is an electrical insulator.

20. The device of claim 13, wherein the source and drain electrodes comprise one or more electrically conductive metals.

21. A process for producing a photo-active device, the process comprising: depositing a source electrode and a drain electrode on a substrate; and either
(a) depositing on the substrate, between the source electrode and the drain electrode, a composition comprising a charge transfer network of single walled carbon nanotubes (SWCNT) such that the network is in contact with the source and drain electrodes to permit electrical current to flow between the source and drain electrodes through the charge transfer network, and depositing on the charge transfer network a solution processible electron trapping material comprising a fullerene compound, or
(b) depositing on the substrate, between the source electrode and the drain electrode, a composition comprising a charge transfer network of single walled carbon nanotubes (SWCNT) homogeneously mixed with a solution processible electron trapping material comprising a fullerene compound to permit electrical current to flow between the source and drain electrodes through the charge transfer network,
wherein in both (a) and (b) the charge transfer network of SWCNT comprises at least 95 wt % of semiconducting single walled carbon nanotubes (sc-SWCNT) based on total weight of the SWCNT, the sc-SWCNT comprising at least 30 wt % of one chiral type of sc-SWCNT based on total weight of the sc-SWCNT,
and wherein in both (a) and (b) the electron trapping material has a lowest unoccupied molecular orbital (LUMO) energy level that is higher in energy than a highest occupied molecular orbital (HOMO) energy level of the one chiral type and at least 0.1 eV lower than a lowest unoccupied molecular orbital (LUMO) energy level of the one chiral type.

22. The process of claim 21, wherein, in part (a), the composition comprising the charge transfer network is deposited on the substrate before the electron trapping material is deposited on the composition comprising the charge transfer network.

23. The process of claim 21, wherein:
the depositing of the charge transfer network is accomplished by printing;
the depositing of the electron trapping material is accomplished by printing; or,
both the depositing of the charge transfer network and the electron trapping material are accomplished by printing.

24. The process of claim 21, further comprising annealing the deposited charge transfer network on the substrate.
